(19) United States
(12) Patent Application Publication
(10) Pub. No.: US 2025/0133709 A1
(43) Pub. Date: Apr. 24, 2025

(54) Component Shielding

(71) Applicant: Google LLC, Mountain View, CA (US)

(72) Inventors: Chien Hua Hsu, New Taipei City (TW); ChanWei Chiu, Taoyuan City (TW); Bing-Feng Wang, New Taipei City (TW); Shen Hao Lee, Taipei City (TW); Jui Hung Hsu, Taipei (TW); Jehyoung Lee, Saratoga, CA (US)

(73) Assignee: Google LLC, Mountain View, CA (US)

(21) Appl. No.: 18/999,262

(22) Filed: Dec. 23, 2024

Related U.S. Application Data
(60) Provisional application No. 63/735,509, filed on Dec. 18, 2024.

(51) Int. Cl. H05K 9/00; H05K 1/02; H05K 1/18

(52) U.S. Cl. CPC H05K 9/0032; H05K 1/0216; H05K 1/181; H05K 9/0081; H05K 2201/10371

(57) ABSTRACT

This document describes a system including a printed circuit board oriented along a first plane, the printed circuit board having a device that extends in a direction away from the first plane and is capable of producing a radiated signal or is sensitive to a radiated signal produced by another device. The system includes a component shield with a wall structure and a cover structure, the cover structure connected to the wall structure. A housing structure oriented along a second plane defines a shielded space within which the component shield and the device reside. A shielding layer oriented along a third plane substantially parallel with the second plane is disposed at least partially between the cover structure and the housing structure and configured to attenuate radiated signals. A number of capacitor spot welds affix the shielding layer to the cover structure to improve component shielding.

### CROSS-REFERENCE TO RELATED APPLICATION(S)

This application claims the benefit of U.S. Provisional Patent Application Ser. No. 63/735,509 filed on Dec. 18, 2024, the disclosure of which is incorporated by reference herein in its entirety.

### SUMMARY

This document describes systems and techniques directed at component shielding for electronic devices through capacitor spot-welding. In some cases, a system includes a printed circuit board (PCB) oriented along a first plane. The PCB has a device that extends in a direction away from the first plane. The device is capable of producing a radiated signal and/or is sensitive to a radiated signal produced by another device. The system includes a component shield having a wall structure and a cover structure, the wall structure oriented perpendicular to the first plane and the cover structure connected to the wall structure and oriented parallel to the first plane. The system further includes a housing structure oriented along a second plane, the second plane being substantially parallel to the first plane and the first and second planes defining a shielded space within which the component shield and the device are disposed. The system further includes a shielding layer oriented along a third plane substantially parallel with the second plane, the shielding layer being disposed at least partially between the cover structure and the housing structure and configured to attenuate radiated signals. The system further includes a capacitor spot weld that affixes the shielding layer to the cover structure. The capacitor spot weld is produced in a technique using capacitor spot-welding that allows for a relatively thin shielding layer in an electronic device (relative to the thickness of shielding layers in conventional electronic devices devoid of capacitor spot welds). This layer is bonded to the cover structure to improve electromagnetic interference shielding without burning the thin shielding layer.

The details of one or more implementations are set forth in the accompanying Drawings and the following Detailed Description. Other features and advantages will be apparent from the Detailed Description, the Drawings, and the Claims. This Summary is provided to introduce subject matter that is further described in the Detailed Description. Accordingly, a reader should not consider the Summary to describe essential features nor the scope of the claimed subject matter.

### BRIEF DESCRIPTION OF THE DRAWINGS

To easily identify the discussion of any particular element or act, the most significant digit or digits in a reference number refer to the figure number in which that element is first introduced.

FIG. 1 depicts a plan view of an example of a component shielding system.

FIG. 2 depicts a cross-sectional view of a component shielding system.

FIG. 3 depicts a cross-sectional view of a capacitor spot-welding system.

FIG. 4 depicts a graph showing a change in resistance per time period.

FIG. 5 depicts a cross-sectional view of an interface between a shielding layer and a cover structure, illustrating a plurality of capacitor spot welds.

FIG. 6 depicts an example environmental view of an example of a component shielding system.

FIG. 7 depicts a cross-sectional view of the component shielding system of FIG. 6.

FIG. 8 depicts an example device diagram of example electronic devices in which component shielding can be implemented.

### DETAILED DESCRIPTION

### Overview

This document describes a shielding architecture within an electronic device directed at improving isolation to mitigate active component desensitization. Many electronic devices include active components such as system-on-chips (SoC). The active components may radiate signals through available openings, causing interference, which may affect antenna performance. Loss of antenna performance can degrade a user experience, such as reduced bandwidth and increased noise, thereby slowing or reducing quality of communications. In an attempt to address these problems, some techniques use adhesives to attach a relatively thick electromagnetic shielding layer to a shielding structure containing a system-on-chip in an attempt to improve electromagnetic shielding.

More specifically, portable electronic devices may include a shielding structure designed to provide an electromagnetic shield to devices on which the shielding structure is placed. The devices may include SoCs that are sensitive to radiated signals or that produce radiated signals. However, as electronic devices become more powerful, the sizes and heights of the chips can increase, which can result in leakage of incoming or outgoing radiated signals. In designs where the shielding structure includes an opening, adhesives may be used to attach a flat electromagnetic shielding layer to the shielding structure to cover the opening of the shielding structure in an attempt to block the radiated signals. As the available areas for attaching the electromagnetic shielding layer reduce, the strength of the attachment may also reduce. Thus, a minimum available area (and thus a minimum width) of an interface between the shielding structure and a conductive pressure-sensitive adhesive is reserved for attachment. Further, in some instances, the thick electromagnetic shielding layer may increase a height of a shielding structure, leading to reduced space for batteries and other valuable components. In other instances, the thick electromagnetic shielding covers may peel off or have uneven surfaces when bonding is insufficient.

To this end, this document describes systems and apparatuses for component shielding within an electronic device through the welding of shielding layers to cover structures of component shields via capacitor spot-welding. Spot-welding is a form of resistance welding that is used to join a plurality of metal sheets together. During spot-welding, pressure and heat are applied to specific spots of the metal sheets to generate a welded joint that bonds the metal sheets together. The pressure may be generated by clamping the metal pieces together or applying another form of pressure to bring the metal sheets into close contact with each other. Upon applying current through a contact point or “spot,” the resistance of the metal at the contact point generates heat causing the metal sheets at the contact point to melt and create a fused metal, which may cool and solidify to form a welded joint. In capacitor spot-welding, the energy source is one or more capacitors. In examples, a capacitor bank may be charged to a high voltage and rapidly discharged through the contact point using a conductor (e.g., a rod).

In examples, a system for capacitor spot-welding improves the bonding of shielding layers to cover structures through the use of a power supply, electrodes, and a control unit configured to deliver and regulate electrical pulses for capacitor spot-welding. The system for capacitor spot-welding may further include a welding architecture configured with a predefined combination of specific welding parameters to spot weld thin shielding layers (e.g., 0.1 mm or less in thickness) to cover structures while maintaining a mechanical integrity of the shielding layer.

Techniques and systems described herein make use of capacitor spot-welding to provide durable bonds and/or seals between the shielding layer and the cover structure. By addressing the attachment of shielding layers to cover structures, not only can the strength and quality of bonds be increased, but also restrictions related to available space for bonding may be reduced and improvements in the thicknesses of shielding structures can be obtained to provide more space for other components, such as to increase battery capacity. This can enable the incorporation of more irregular three-dimensional (3D) structures or chips without compromising shielding quality.

The following discussion describes operating environments and techniques that may be employed in the operating environments and example methods. Although systems and techniques directed at component shielding for electronic devices are described, it is to be understood that the subject of the appended Claims is not necessarily limited to the specific features or methods described. Rather, the specific features and methods are disclosed as example implementations and reference is made to the operating environment by way of example only.

### Example Device

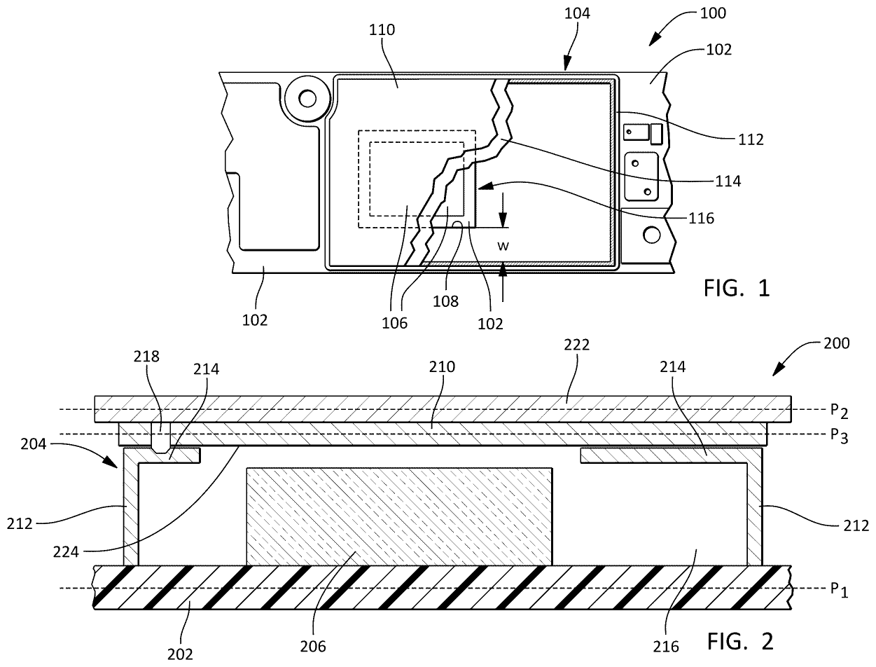

An electronic or computing device (e.g., smartphone, tablet computer, mobile electronic device) includes a number of internal components located within a housing. FIG. 1 illustrates a plan view of an example of a component shielding system 100 of a computing device in accordance with this disclosure, the system 100 including a printed circuit board 102 (PCB 102), a component shield 104, a device 106, an aperture 108, a shielding layer 110, and at least one wall structure 112. The electronic device includes a substrate, such as the PCB 102 (e.g., main board, system board, motherboard) that includes the device 106 that extends in a direction away from the PCB 102 and/or a plane of the PCB 102. For example, in the plan view of FIG. 1, the device 106 extends outward in the direction towards the viewer.

The device 106 may include an active component (e.g., integrated circuit chip, transceiver chip, system-on-chip (SoC), central processing unit (CPU), antenna) that radiates signals (e.g., electromagnetic waves, radio frequency (RF) radiation) that may cause electromagnetic interference (EMI). In examples, the device 106 includes one or more active components (e.g., an antenna) or passive components that are sensitive to radiated signals. In examples, the device 106 may be an SoC and the system 100 may include an antenna sensitive to radiated signals. To mitigate electromagnetic interference, a component shield (e.g., shielding can, component shielding, component radiation shield) that forms an electromagnetic shield may be installed over the device 106. For example, the component shield 104 may be installed over the device 106 on the PCB 102 to mitigate electromagnetic interference produced by the device 106 to prevent interference and/or shield the device 106 from effects of electromagnetic interference from sources external to the device 106. The component shield 104 may be surface mounted to the PCB 102 through a soldering process or may be otherwise positioned relative to the PCB 102. The component shield 104 may include at least one wall structure 112 (e.g., sidewall) and at least one cover structure 114 (e.g., overhang structure).

The cover structure 114 may include the aperture 108 defined therethrough. The aperture 108 may permit access to the device 106 after the component shield 104 is installed on the PCB 102 and/or may provide ventilation for the device 106. The aperture 108 through the cover structure 114 may be covered with the shielding layer 110 to prevent radiated signals from passing through the aperture 108. In the example illustrated in FIG. 1, the shielding layer 110 is planar and includes a capacitor spot welded portion (not illustrated). The shielding layer 110 is applied to the cover structure 114 to cover the aperture 108. When a component shield 104 is installed on a PCB 102, a shielded space is defined. For example, in FIG. 1 the component shield 104 installed on the PCB 102 (with the shielding layer 110 covering the aperture 108) defines a shielded space 116 between the PCB 102, the component shield 104, and the shielding layer 110. The shielded space 116 surrounds at least a portion of the device 106. In some examples, the aperture 108 in the cover structure 114 of the component shield 104 is located in a position adjacent to the wall structure 112. In such a configuration, a width (w) of the cover structure 114 between the wall structure 112 and the aperture 108 may not provide a sufficient surface area to suitably bind with a conventional adhesive of the shielding layer 110. Further, welding the shielding layer 110 to the cover structure 114 without taking into consideration a thickness of the shielding layer 110 may cause burning of the shielding layer 110. In an example, the width is less than three millimeters (3 mm). If the shielding layer 110 is not properly affixed along the width of the cover structure 114, the shielding layer 110 may deform (e.g., an edge of the shielding layer 110 may peel, a fold may form in the shielding layer 110, a crease may form in the shielding layer 110). If the shielding layer 110 deforms, a gap in the protection offered by the component shield 104 may permit electromagnetic radiation to pass through the aperture 108 and into or out of the shielded space 116, potentially causing electromagnetic interference. To avoid such gaps, a manufacturer may perform capacitor spot-welding between the shielding layer 110 and the cover structure 114 to provide a robust bonding of the shielding layer 110 and the cover structure 114 that prevents radiated signal leakage.

FIG. 2 illustrates a cross-section of an example component shielding system 200 including a PCB 202, a component shield 204, a device 206, a shielding layer 210, a wall structure 212, a cover structure 214, a shielded space 216, a capacitor spot weld 218, and a housing structure 222. As shown in the figure, the PCB 202 is disposed in a first plane P1. A height of the device 206 extends in a direction away from the first plane P1. The wall structure 212 is oriented perpendicular to the first plane P1. The cover structure 214 is connected to the wall structure 212 and oriented parallel to the first plane P1. The housing structure 222 is oriented along a second plane P2. The housing structure 222 may include one or more of a computing device housing, frame, midframe, mount, mounting structure, case, plate, front, sidewall, back, cover, or portion thereof.

The second plane P2 is substantially parallel to the first plane P1. The first and second planes define the shielded space 216 within which the component shield 204 and the device 206 reside. In examples, the shielded space 216 is defined between the PCB 202, interior walls of the wall structure 212 and the cover structure 214, and a portion of the shielding layer 210.

The shielding layer 210 is positioned at least partially between the cover structure 214 and the housing structure 222. The shielding layer 210 is configured to attenuate a radiated signal. The shielding layer 210 is oriented along a third plane P3, which is substantially parallel with the second plane P2. The shielding layer 210 resides in the defined shielded space 216.

The shielding layer 210 is affixed to the cover structure 214 through the capacitor spot weld 218. To mitigate burning of the shielding layer 210 during capacitor spot-welding, parameters of the capacitor spot-welding are carefully designed to facilitate a tight bond and an undamaged shielding layer 210.

In some examples, the shielding layer 210 comprises a foil. In some examples, the foil is a copper foil (e.g., copper layer, copper laminate, copper material, copper sheet). In examples, the foil is at least fifty percent (50%) elemental copper. The foil may include a side 224 that is configured for contacting a surface, such as the surface of the cover structure 214, as is illustrated in FIG. 2.

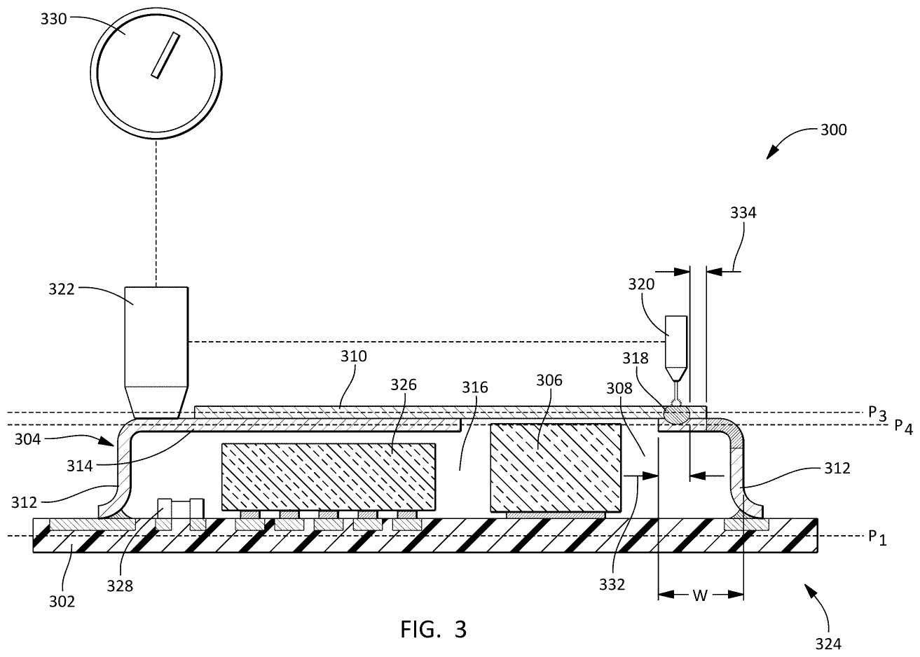

FIG. 3 illustrates a capacitor spot-welding system 300 including a PCB 302, a component shield 304, a device 306, an aperture 308, a shielding layer 310, a wall structure 312, a cover structure 314, a shielded space 316, at least one capacitor spot weld 318, a rod 320, and a grounding electrode 322. The capacitor spot-welding system 300 is used for capacitor spot-welding the shielding layer 310 to the cover structure 314 of a component shielding system 324. The component shielding system 324 is similar to the component shielding system 100 illustrated in FIG. 1 or the component shielding system 200 illustrated in FIG. 2 but includes one or more other devices (326, 328). The component shielding system 324 includes the PCB 302 having the device 306 and the other devices (326, 328) that may be capable of producing a radiated signal or that are sensitive to a radiated signal produced by another device. The component shielding system 324 includes the component shield 304 having the wall structure 312 and the cover structure 314 with the aperture 308 defined therethrough. The component shielding system 324 further includes the shielded space 316 within which the component shield 304 and the device 306 reside. The shielding layer 310 is bonded or affixed to the cover structure 314 through the at least one capacitor spot weld 318.

Unlike other spot-welding systems, the capacitor spot-welding system 300 is designed with a parameter control module 330 to address the burning of thin shielding layers and/or cover structures during the spot-welding process. Under the combined actions of heat and pressure provided by at least the rod 320, the points of contact between the shielding layer 310 and the cover structure 314 melt and combine with each other to form a strong joint. The parameter control module 330 may be configured to provide, through a closed circuit formed between the rod 320 and the grounding electrode 322, a voltage of 4.5V, a current of 200-250 A, a transient discharge duration of 0.3 millimeters (mm), and a contact force of 2-10 g. By providing this combination of capacitor spot-welding parameters, a shielding layer 310 of 0.04 mm can be capacitor spot welded to the cover structure 314 without burning the shielding layer 310 or the cover structure 314. These parameters may enable molten metal formed to solidify after cooling, forming a strong welded joint that remains intact and possesses a desired welding integrity for electronic devices.

In examples, a width W of the cover structure 314 in a fourth plane P4 is reduced from at least 2 mm to at least 0.7 mm due to an ability to generate a strong bond with the capacitor spot weld 318 while maintaining or enhancing electromagnetic shielding. More specifically, in an example component shielding system 324 comprising a corner radius of the wall structure 312 of about 0.2 mm, a thickness of the wall structure 312 of about 0.1 mm, and a thickness of the shielding layer 310 of about 0.04 mm, a spot-welding range 332 of 0.2 mm to 0.25 mm can be achieved by methods and structures described herein. Further, a shielding layer tolerance 334 of 0.2 mm can be achieved. Even further, a shortest return path for the electric circuit formed between the rod 320 and the grounding electrode 322 can be reduced to a minimum size of 1.5 mm in diameter, not only optimizing the spatial arrangement of the components of the component shielding system 324 but also offering flexibility in the design of component shielding systems.

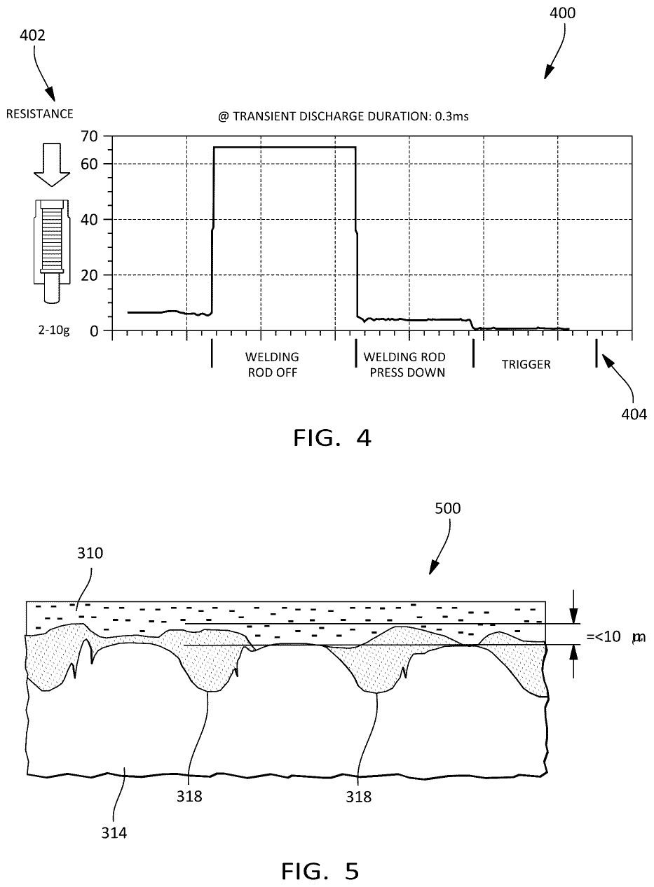

FIG. 4 shows a graph 400 illustrating changes in resistance 402 at different time periods 404 of the capacitor spot-welding process performed using a capacitor spot-welding system such as the capacitor spot-welding system 300 of FIG. 3. Prior to applying the rod 320 to the shielding layer 310 with a force of 2-10 g, a measured impedance (vertical axis 402) between the rod and grounding electrode is relatively high (for example, between 60 to 70 ohms). Upon applying the rod 320 to the shielding layer 310, the impedance 402 reduces to a relatively low impedance of about 4-5 ohms. Responsive to activating the capacitor spot-welding system 300, to discharge energy through a contact point between the shielding layer 310 and the cover structure 314, the impedance reduces to close to 0 ohms (for example between 0.1 and 2 ohms). A total duration of the discharge process is about 0.3 milliseconds (ms) (for example 0.3 ms +/−1-30%). In examples, other ranges of the welding parameters may include a voltage of 4.5V (+/−1-20%), a current of 200-250 A, and a contact force of 2-10 g.

Under the combined actions of heat and pressure, points of contact between the shielding layer 310 and cover structure 314 proximal to the rod 320 fuse with each other to form a strong joint as shown in FIG. 5.

FIG. 5 illustrates a cross-section of an interface 500 between the shielding layer 310 and the cover structure 314, (as described with reference to FIG. 3) illustrating a plurality of capacitor spot welds 318. As shown in the figure, even though the shielding layer 310 is fused with the cover structure 314, the shielding layer 310 remains unburned due to the nature of the capacitor spot-welding process disclosed herein.

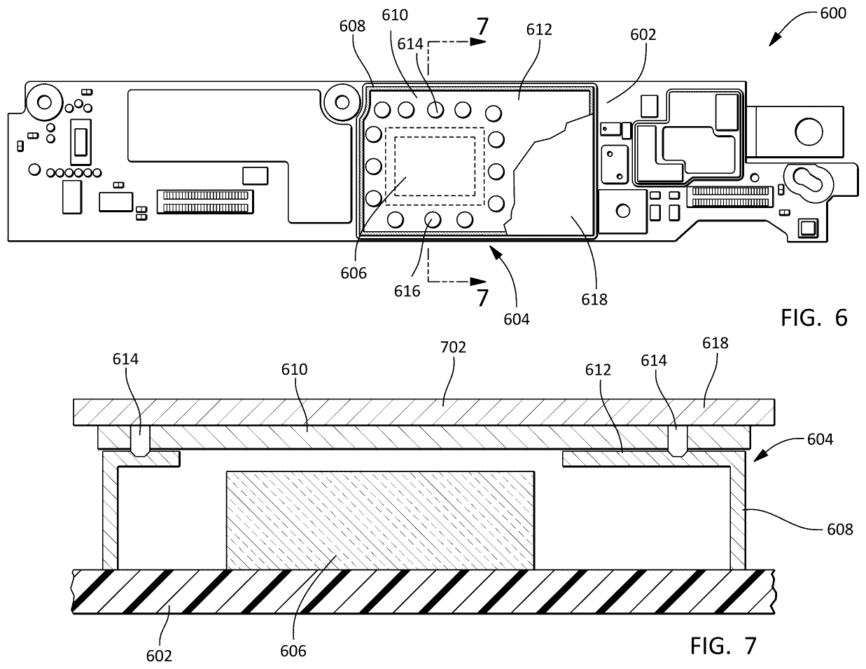

FIG. 6 depicts an example environmental view of an additional example of a component shielding system 600, and FIG. 7 is a side sectional view of the component shielding system 600 of FIG. 6. The component shielding system 600 is similar to the component shielding system 324 illustrated in FIG. 3 and described above, except as detailed below. The component shielding system 600 includes a PCB 602, a component shield 604, a device 606, a wall structure 608, a shielding layer 610, and a cover structure 612. The device 606 may extend in a direction away from a first plane P1 (see FIG. 3). The shielding layer 610 is similar to the shielding layers (110, 210, 310) respectively illustrated in FIGS. 1, 2, and 3 and described above, except as detailed below. Thus, the shielding layer 610 includes at least a first capacitor spot weld 614 and a second capacitor spot weld 616. In examples, a plurality of capacitor spot welds including the first capacitor spot weld 614 and the second capacitor spot weld 616 affix the shielding layer 610 to the cover structure 612. The component shielding system 600 also includes a housing structure 618.

FIG. 7 illustrates a side sectional view of the component shielding system 600 of FIG. 6 including a face 702 of the shielding layer 610 that contacts the housing structure 618. The shielding layer 610 is disposed in a region between the cover structure 612 and the housing structure 618. The side sectional view depicts the first capacitor spot weld 614 and the second capacitor spot weld 616 at different sides of the cover structure 612.

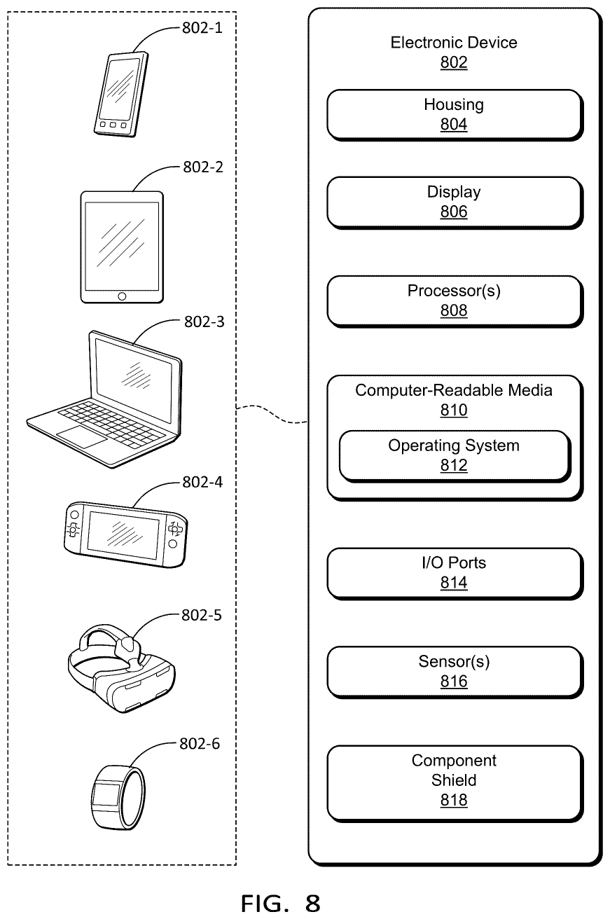

FIG. 8 illustrates an example device diagram of an example electronic device 802 in which component shielding can be implemented. The electronic device 802 may include additional components and interfaces omitted from FIG. 8 for the sake of clarity.

The electronic device 802 can be any of a variety of consumer electronic devices. As non-limiting examples, the electronic device 802 can be a mobile phone 802-1, a tablet device 802-2, a laptop computer 802-3, a portable video game console 802-4, virtual-reality (VR) goggles 802-5, a computerized watch 802-6, and or any communication device.

The electronic device 802 includes a housing 804 (such as the housing structure 618) and a display 806, which define at least one internal cavity within which one or more of a plurality of electronic components may be disposed. In implementations, a middle frame may define one or more portions of the housing 804. As an example, a middle frame can include plastic or metallic walls that define portions of the housing 804. In additional implementations, a middle frame may support one or more portions of the housing 804. As an example, one or more exterior housing components (e.g., plastic panels) can be attached to the middle frame (e.g., a chassis). In so doing, the middle frame may physically support the one or more exterior housing components, which define portions of the housing 804. In implementations, the middle frame and/or the exterior housing components may be composed of crystalline or non-crystalline (e.g., metals, plastics) inorganic solids.

The electronic device 802 may further include one or more processors 808. The processor(s) 808 can include, as non-limiting examples, an SoC, an application processor (AP), a CPU, or a graphics processing unit (GPU). The processor(s) 808 generally execute commands and processes utilized by the electronic device 802 and an operating system installed thereon. For example, the processor(s) 808 may perform operations to display graphics of the electronic device 802 on the display 806 and can perform other specific computational tasks.

The electronic device 802 may also include computer-readable storage media (CRM) 810. The CRM 810 may be a suitable storage device configured to store device data of the electronic device 802, user data, and multimedia data. The CRM 810 may store an operating system 812 that generally manages hardware and software resources (e.g., the applications) of the electronic device 802 and provides common services for applications stored on the CRM 810. The operating system 812 and the applications are generally executable by the processor(s) 808 to enable communications and user interaction with the electronic device 802. One or more processor(s) 808, such as a GPU, perform operations to display graphics of the electronic device 802 on the display 806 and can perform other specific computational tasks. The processor(s) 808 can be single-core or multiple-core processors.

The electronic device 802 may also include input/output (I/O) ports 814. The I/O ports 814 allow the electronic device 802 to interact with other devices or users. The I/O ports 814 may include any combination of internal or external ports, such as universal serial bus (USB) ports, audio ports, Serial ATA (SATA) ports, peripheral component interconnect express (PCIe) based ports or card-slots, secure digital input/output (SDIO) slots, and/or other legacy ports.

The electronic device 802 may further include one or more sensors 816. The sensor(s) 816 can include any of a variety of sensors, such as an audio sensor (e.g., a microphone), a touch-input sensor (e.g., a touchscreen), an image-capture device (e.g., a camera, video-camera), proximity sensors (e.g., capacitive sensors), an under-display fingerprint sensor, or an ambient light sensor (e.g., photodetector). In implementations, the electronic device 802 includes one or more of a front-facing sensor(s) and a rear-facing sensor(s).

The electronic device 802 may also include a component shield 818 (e.g., component shields 104, 204, 304, 604) configured to enhance antenna performance, make a bonding of shielding layers to the component shield 818 strong enough to pass drop testing, and reduce a minimum width of cover structures available for bonding from 2 mm to 0.7 mm.

The disclosed techniques and apparatuses directed to capacitor spot-welding for component shielding allow for improved bonding of a shielding layer to a cover structure of a component shield of an electronic device, such as a smartphone. Improved bonding can prevent radiated signals from leaking out from or into a shielded space of the component shield and provide flexibility in the design of the electronic device.

The preceding discussion describes techniques and apparatuses directed to component shielding. Although techniques and apparatuses directed to component shielding are described, it is to be understood that the subject of the appended Claims is not necessarily limited to the specific features or methods described. Rather, the specific features and methods are disclosed as example implementations, and reference is made to the operating environment by way of example only.

As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, c-c-c, or any other ordering of a, b, and c).

Although implementations of techniques and apparatuses directed to component shielding have been described in language specific to certain features and/or methods, the subject of the appended Claims is not necessarily limited to the specific features or methods described. Rather, the specific features and methods are disclosed as example implementations of a component shield.

What is claimed is:

1. A system comprising:
a printed circuit board oriented along a first plane, the printed circuit board having a device that extends in a direction away from the first plane and is capable of producing a radiated signal or is sensitive to a radiated signal produced by another device;
a component shield having a wall structure and a cover structure, the wall structure oriented perpendicular to the first plane, and the cover structure connected to the wall structure and oriented parallel to the first plane;
a housing structure oriented along a second plane, the second plane being substantially parallel to the first plane, and defining a shielded space within which the component shield and the device reside;
a shielding layer oriented along a third plane substantially parallel with the second plane, the shielding layer being disposed at least partially between the cover structure and the housing structure and configured to attenuate radiated signals; and
a capacitor spot weld affixing the shielding layer to the cover structure.

2. The system of claim 1, wherein the shielding layer comprises a foil.

3. The system of claim 2, wherein the foil comprises copper.

4. The system of claim 1, wherein a minimum width in a fourth plane of the cover structure of the component shield is 0.7 mm.

5. The system of claim 1, wherein a plurality of capacitor spot welds including the capacitor spot weld affix the shielding layer to the cover structure around a periphery of an aperture of the component shield.

6. The system of claim 1, wherein a thickness of the shielding layer is about 0.04 mm and a thickness of the cover structure is about 0.1 mm.

7. The system of claim 1, wherein a diameter of the capacitor spot weld is from 0.2 to 0.25 mm.

8. The system of claim 1, wherein the system is disposed in an electronic device.

9. The system of claim 1, wherein the device is a system-on-chip (SoC).

10. The system of claim 1, wherein the housing structure is a midframe of an electronic device.
